(19) United States
(12) Patent Application Publication
(10) Pub. No.: US 2014/0168913 A1
(43) Pub. Date: Jun. 19, 2014

(54) METHOD AND APPARATUS FOR REDUCING STRESS ON MOUNTED ELECTRONIC DEVICES

(71) Applicant: Enphase Energy, Inc., Petaluma, CA (US)

(72) Inventor: Martin Fornage, Petaluma, CA (US)

(73) Assignee: Enphase Energy, Inc., Petaluma, CA (US)

(21) Appl. No.: 14/104,576

(22) Filed: Dec. 12, 2013

Related U.S. Application Data
(60) Provisional application No. 61/738,766, filed on Dec. 18, 2012.

(51) Int. Cl. H05K 1/02

(52) U.S. Cl. CPC H05K 1/0271
USPC 361/748

(57) ABSTRACT

A continuous substrate including a first portion with a plurality of electronic components, and at least one strain relief area located proximate a fastening location, wherein the at least one strain relief area is located between the first portion and the fastening location.

### CROSS-REFERENCE TO RELATED APPLICATION

This application claims priority to U.S. Provisional Patent Application No. 61/738,766 filed on Dec. 18, 2012, which is incorporated by reference herein in its entirety.

### BACKGROUND

1. Field

Embodiments of the present invention generally relate to an electronic device, and more particularly, relate to a method and apparatus for reducing stress when mounting an electronic device, for example, a printed circuit (PC) board.

2. Description of the Related Art

Electronic devices utilized in systems for generating energy from renewable resources, such as solar power systems, wind farms, hydroelectric systems, or the like, may be exposed to environment elements and typically placed in a housing enclosure. Such electronic devices are often secured to a housing using multiple screws. The electronic devices may include printed circuit boards (PCBs) and other substrates used in inverters, converters, power supplies, or the like.

Unfortunately, an excess amount of force exerted in tightening the screws may damage the PCBs, especially when mounting standoffs are not coplanar. Furthermore, environmental factors such as temperature change and power generation produces heat that directly or indirectly may result in the bending of the PCB, and ultimately damaging the PCB and circuitry. For example, potting material placed in the enclosure between an inner wall of the enclosure and PCB may contract and expand from changes in temperature. Strain on the PCB also results from the temperature coefficient mismatch between the enclosure and PCB. The contraction and expansion thus may place undue physical stress on mounted electronic components and PCB that is fixed to the enclosure by hardware fasteners.

Electronic components, especially surface mount components such as resistors, capacitors, ICs, transistors and the like, cannot tolerate repetitive low stress (e.g., 500 microstrain). Often, large “keep out” areas around mounting holes void of electronic parts are used to allow stress to dissipate before electronic components are encountered. However, such a method wastes PCB material and increases materials costs.

Therefore, there is a need in the art for an improved method and apparatus for reducing the stress on mounted electronic devices.

### SUMMARY

Embodiments of the present invention generally relate to a method and apparatus for reducing stress on a mounted electronic device and associated electronic components as shown in and/or described in connection with at least one of the figures, as set forth more completely in the claims.

Various advantages, aspects and novel features of the present disclosure, as well as details of an illustrated embodiment thereof, will be more fully understood from the following description and drawings.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a top perspective view of an electronic device mounted in an enclosure in accordance with some embodiments of the present invention;

FIG. 2 is a cutaway view of an electronic device potted and attached within an enclosure of FIG. 1 taken along line 2-2 in accordance with some embodiments of the present invention;

FIG. 3 is a top plan view of an exemplary area on the electronic device in accordance with at least one embodiment of the invention;

FIG. 4 is a top plan view of an exemplary area on the electronic device in accordance with at least one embodiment of the invention;

FIG. 5 is a detailed perspective view of an exemplary area on the electronic device in accordance with some embodiments of the present invention; and

FIG. 6 is a flow diagram of a method for excavating stress relief areas in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

A method and apparatus for reducing stress on a mounted electronic device are provided herein. Embodiments of the present invention reduce strain at the connection point between hardware fasteners and the electronic devices such as printed circuit boards (PCBs) by thinning or removing entirely material proximate to the connection point.

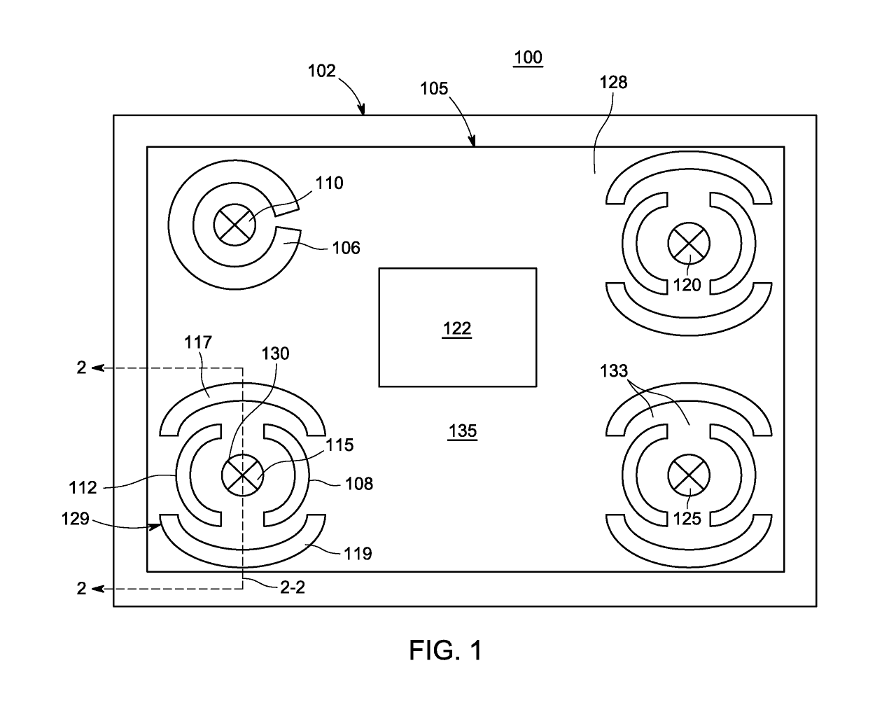

FIG. 1 depicts a top perspective view of an electronic device mounted in an enclosure in accordance with some embodiments of the present invention. The apparatus 100 of FIG. 1 comprises an enclosure 102, an electronic device 105, strain relief areas (e.g., 108 and 112), and hardware fasteners (110, 115, 120, and 125). The strain relief areas (e.g., 108, 112, 117, 119) are depicted as symmetrical pairs of equidistant spacing to the center of the fastener 115, for equal force dissipation. The symmetrical pairs include a first pair (e.g., 108, 112) of a smaller area than a second pair (e.g., 117, 119) that partially encompasses the first pair (e.g., 108, 112). However, non-symmetrical strain relief areas may be included. Alternative embodiments may also include a single continuous strain relief area 106 substantially surrounding and concentric with a hardware fastener 110. As depicted in the apparatus 100, relief patterns on a substrate 128 may be mixed or homogenous.

In some embodiments, the electronic device 105 comprises a substrate 128 that is rigid and continuous. Furthermore, while the depicted embodiment shows fasteners (110, 115, 120, 125), the occupied area also includes through holes of the electronic device 105 and/or substrate 128.

Hardware fasteners (110, 115, 120, 125) secure the electronic device and/or substrate 128 to the enclosure 102 via the through holes (not shown). The enclosure 102 may be any suitably sized enclosure for enclosing the electronic device 105. Although a rectangular shape is depicted in FIG. 1, the enclosure 102 may be any other suitable shape for containing the electronic device 105, such as cylindrical, square, circular, oval, or the like. The enclosure 102 may be formed from metal, plastic, or a combination thereof.

For example, in some embodiments the enclosure 102 may serve as an electromagnetic interference (EMI) shield and may therefore be formed at least partially from metal, such as steel, aluminum, or the like. In some alternative embodiments, the enclosure 102 may be formed from plastic when another component, is utilized as an EMI shield. However, the enclosure 102 may also have no shielding and be formed from polymer plastics.

Further embodiments may have more than or less than four hardware fasteners (110, 115, 120, 125) depending on the size of the electronic device 105 to be mounted to the enclosure 102. Hardware fasteners (110, 115, 120, 125) may be suitably sized based on the attachment needs of the electronic device 105 and may be comprised of screws, bolts, rivets, and/or the like. The composition of the hardware fasteners (110, 115, 120, 125) may be selected to accurately fit with the enclosure 102 and such that there is no corrosion or reaction between materials.

The electronic device 105 may be any suitable electronic device or substrate 128 that requires physical attachment to the enclosure 102 through hardware fasteners (110, 115, 120, 125). Proximate to the fasteners (110, 115, 120, 125) are a series of relief areas (e.g., 108, 112) that relieve strain asserted on the electronic device 105 from the fasteners (110, 115, 120, 125). By etching to thin a portion or completely removing the substrate material in the relief areas (108, 112, 117, 119) the substrate 128 is given increased ductility properties. The increased ductility allows the substrate 128 proximate the relief areas (108, 112) to bend against physical forces and strain exerted between the fastener 115 and the substrate. Mounting forces are strongest closest to a junction between the fastener 115 and the substrate 128. Thus, upon external stress factors, such as expanding potting material, the relief areas (e.g., 108, 112) alleviate tension on the substrate 128 that would otherwise translate into strain on mounted electronic components and stress fractures or cracking in the substrate 128 proximate the fastener 115.

Thus, the substrate 128 comprises a first portion 135 (external to the relief areas) with electronic components 122, a second portion 129 comprising the strain relief areas (e.g., 108, 112), a third portion 130 for mounting the fasteners (110, 115, 120, 125), and a fourth portion 133 located between the strain relief areas. The third portion 130 and fourth portion 133 allows the first portion 135 to remain substantially stable. The third portion 130 is proximate to and directly in beneath and in physical contact with the fastener (e.g., 115). The third portion 130 is an area for mounting the fastener (e.g., 115) to the substrate 128, the substrate 128 becoming increasingly stiff with proximity to the fastener (e.g., 115) and/or fastener hole (not shown). The fourth portion 133 are areas of the substrate 128 between the strain relief areas (e.g., 108, 112). The fourth portion 133 is continuously coupled to the third portion 130 and allows movement with the strain relief areas (e.g., 108, 112) while the first portion 135 is relatively stationary.

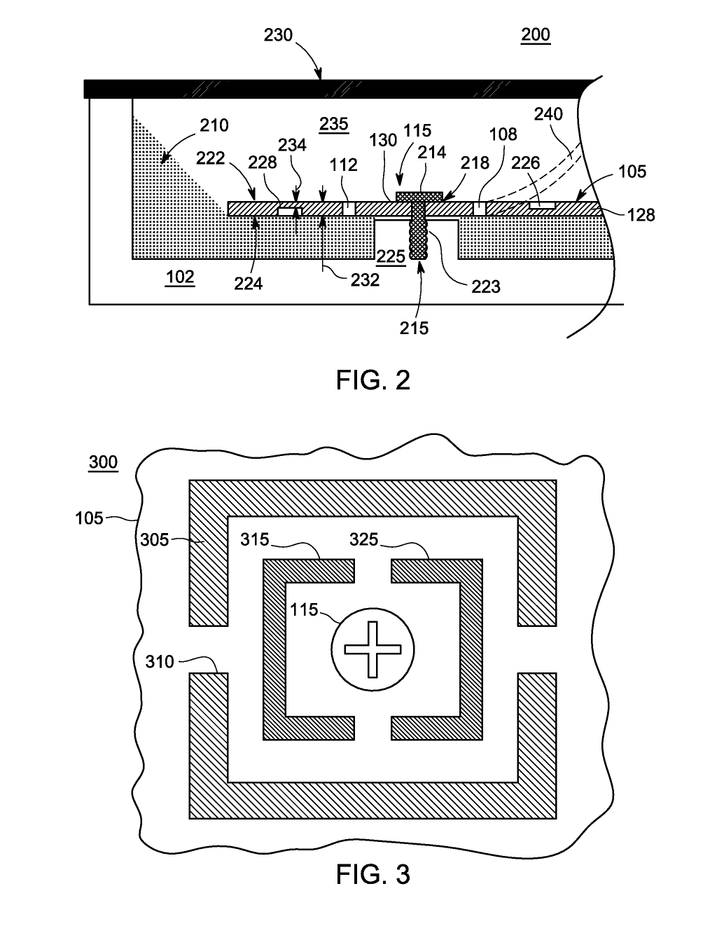

Electronic components 122 may include integrated circuits, transistors, inductors, transformers, capacitors, resistors, or the like, are disposed, for example, on an upper surface of the electronic device 105. The electronic components are mounted to the substrate 128 via conventional means (e.g., soldering, and the like). Examples of the electronic device 105 may be, but are not limited, to PCBs comprised of fiberglass such as FR4. The enclosure 102 may also house potting material (not shown) to partially or totally fill the enclosure and seal the electronic device 105 from potentially damaging elements, such as moisture, air, salt, acid, or the like as will be further discussed in FIG. 2.

FIG. 2 is a cutaway view of an electronic device 105 potted and attached within an enclosure 102 of FIG. 1 taken along line 2-2 in accordance with some embodiments of the present invention. The apparatus 200 comprises an enclosure 102 with lid 230, a fastener 115, electronic device 105, and in some embodiments, fill 210. Such embodiments may not include potting material, as one large contributing factor to repetitious strain on the substrate 128 is from the temperature coefficient mismatch between the enclosure 102 and substrate 128.

The electronic device 105 in this embodiment is the substrate 128 that attaches to the enclosure 102 using a fastener 115. When strain occurs, the relief areas allow the attachment point to remain stable and the substrate 128 to move without fracturing the substrate 128 at the attached point. The substrate 128 comprising a top surface 222 and a bottom surface 224 of a first height 232 (e.g., 1.5 mm). The substrate 128 is substantially rigid, but may bend due to the expanding or contracting fill 210 as illustrated by position 240. The substrate 128 comprises relief areas (108, 112, 226, 228) and junction 218. The relief areas (108, 112, 226, 228) improve flexibility of the electronic device 105 proximate to the junction 218. The junction 218 may include a through hole for the fastener 115 as well as the third portion 130 for mounting.

Some relief areas are slots (e.g., 226, 228) and may be formed from partial removal of substrate material to a second thickness 234 (e.g., 1 mm) that is less than the first thickness 232. Other relief areas (e.g., 108, 112) may comprise a through channel extending from the top surface 222 to the bottom surface 224 of the substrate 128. As will be described with respect to FIGS. 3-5, the relief areas (108, 112, 226, 228) may be of various shapes (arcuate, tangential, quadrilateral, orthogonal, and the like) and sizes surrounding the fastener 115. Further embodiments may include a single continuous relief area (not shown) substantially surrounding the fastener.

In this embodiment, the fastener 115 is a screw that has a head 214 and a shaft 215. The shaft 215 has threads 223 to attach to a standoff 225 integrated as a part of the enclosure 102. The standoff 225 in this embodiment is part of the enclosure 102, however other embodiments may include standoffs that are seperably attached as spacers such that the electronic device 105 is not in direct physical contact with the enclosure 102. The standoff 225 shape may be cylindrical, square, circular, hexagonal, oval, or the like, formed from metal, plastic, or a combination thereof. Furthermore, the embodiments of the relief areas (108, 112, 226, 228) allow for the mounting surface of standoff 225 of the enclosure under the fastener 115 to be not perfectly coplanar.

The enclosure 102 surrounds an empty volume 235, with the area between the electronic device 105 and the enclosure 102 is in some embodiments, optionally occupied by a fill 210. The fill 210 may be flexible and is a potting material to prevent exposure to an environment comprising one or more of air, moisture, salt, acid, or the like. Potting may include, for example, placing the electronic device 105 in an enclosure 102, such as a metal or plastic box, and filling the box with a packaging material to encase the electronic device 105 and seal the electronic device 105 from air and environmental elements. Potting materials may include polymers, such as polyurethane or epoxy, or other materials, such as silicone. The embodiment in FIG. 2 depicts the fill 210 on two sides of the electronic device 105 but further embodiments may include fill 210 completely surrounding the electronic device 105.

Alternative embodiments may not use a fastener to attach the electronic device 105 and substrate 128 to the enclosure 102. In such embodiments, locating pegs in the enclosure 102 may be aligned with holes in the substrate 128. Should geometric tolerances not be held properly on the hole/peg mounting array, strain relief areas would self-center the substrate 128 on associated pegs at a minimum mean stress average.

FIG. 3 is a top plan view of an exemplary area on the electronic device 105 in accordance with at least one embodiment of the invention. FIG. 3 depicts an apparatus 300 comprising the electronic device 105, fastener 115, and relief areas (305, 310, 315, and 325 hereinafter referred to as 305-325) on the electronic device 105. Relief areas (305-325) comprise quadrilateral areas of the electronic device 105 that are thinned, tapered, or removed entirely. Relief areas (305-325) improve flexibility and ductility to relieve strain when the fill 210 expands near the electronic device 105 and presses against the fastener 115. The relief areas (305-325) may be etched onto multiple surfaces of the electronic device 105 using a tool such as a dremel or router typically used in making PCBs. While the example depicted in FIG. 3 depicts perpendicular corners in the relief areas (305-325), further embodiments may be tapered and/or rounded. Further still, are embodiments with non-uniform spacing between relief areas (305-325).

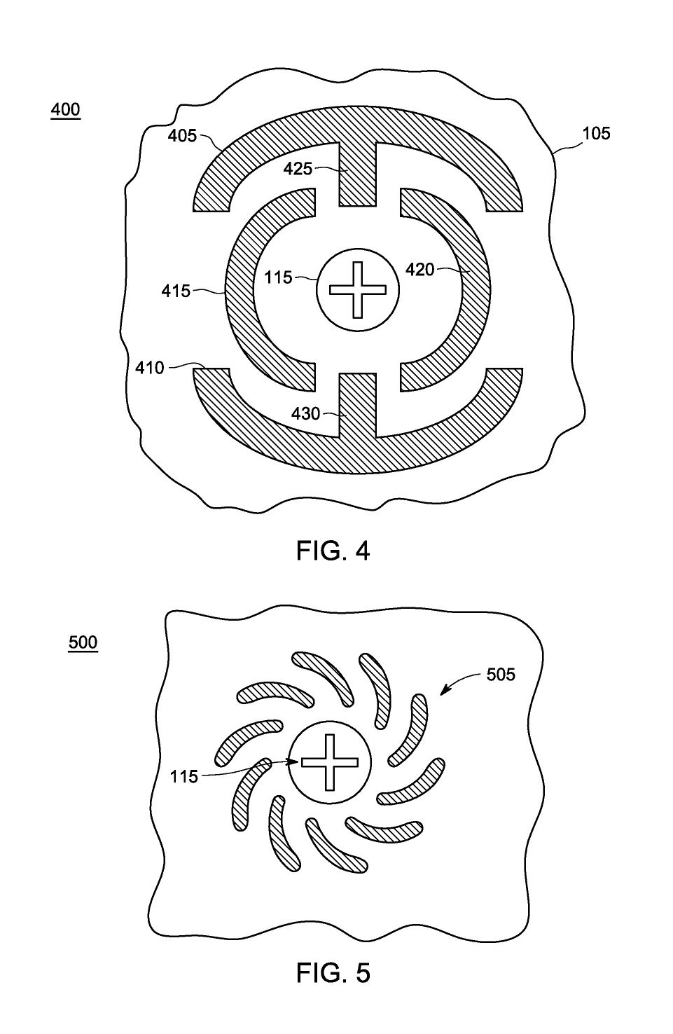

FIG. 4 is a detailed perspective view of exemplary area on the electronic device 105 in accordance with some embodiments of the present invention. FIG. 4 depicts an apparatus 400 comprising the electronic device 105, fastener 115, and relief areas (405, 410, 415, and 420 hereinafter referred to as 405-420) on the electronic device 105. Relief areas (405-420) comprise arcuate areas of the electronic device 105 that are thinned, tapered, or removed entirely proximate to the fastener hole (not shown). Relief areas (405-420) may be orthogonal opposite to one another and generally improve flexibility and ductility of the electronic device against the fastener 115. The apparatus 400 includes within the relief areas (405-420) additional leg regions (425 and 430) that extend from respective arcuate relief areas (405 and 410) towards the fastener 115. Other embodiments may or may not incorporate the leg regions (425 and 430) and comprise only a series of concentric arcuate regions (405-420) surrounding the hardware fastener. The relief areas (405-420) may be etched onto multiple surfaces of the electronic device 105 using a tool such as a dremel or router. While the example depicted in FIG. 4, depicts sharp corners in the relief areas (405-420) further embodiments may be tapered and/or rounded. Further still, are embodiments with non-uniform spacing between relief areas (405-420).

FIG. 5 is a detailed perspective view of an exemplary area on the electronic device 105 in accordance with some embodiments of the present invention. FIG. 5 depicts a series of repeated spiral stress relief areas 505 surrounding the fastener 115. The spiral stress relief areas 505 provide maximum compliance in a shared Z-axis of the fastener while resisting X and Y axis side movements such as in embodiments where the fastener 115 is a rivet. In other embodiments where the fastener 115 is a screw, strain from tightening the screw are also relieved and even more so by the spiral stress relief areas 505 depicted in FIG. 5. The spiral shapes surrounding the fastener 115 provides rotational resistance in order to prevent damage from torque applied to the screw during assembly.

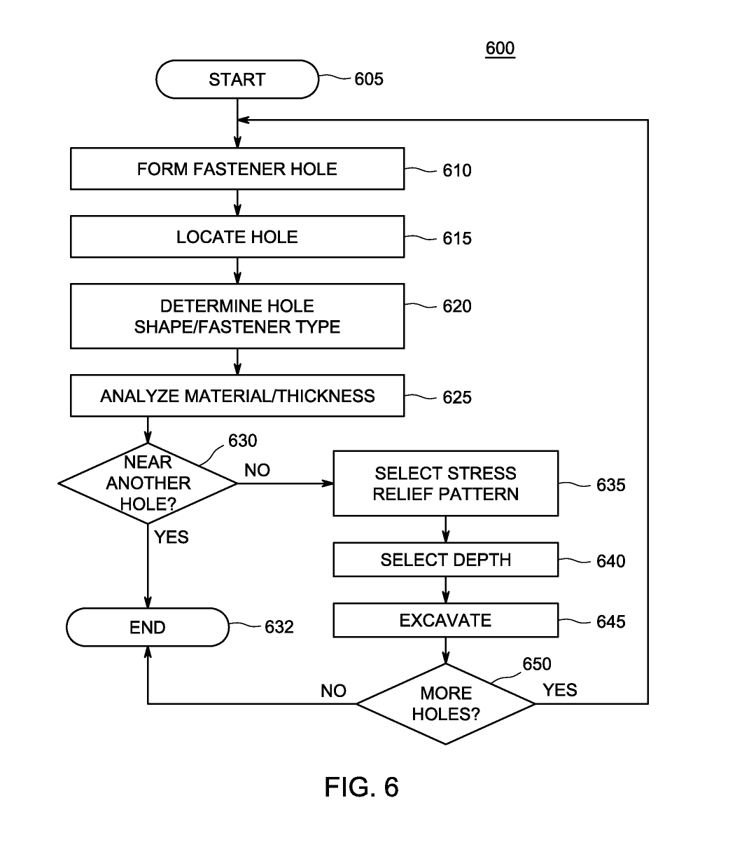

FIG. 6 is a flow diagram of a method for excavating stress relief areas in accordance with some embodiments of the present invention. The method 600 begins at step 605 with forming a hole for fasteners at step 610 in the electronic device 105 and/or substrate 128. Holes may be formed by drilling, etching, laser cutting, and the like in the diameter necessary to allow the shaft 215 of the desired fastener to pass through the hole. Next the hole is located at step 615. Once located, the method proceeds to step 620 to determine the shape of hole and the fastener type.

Determining the shape includes the area, diameter, and features of the fastener hole. The fastener hole type may also be determined by the type of fastener 115 to be used (e.g., screw, nail, rivet, bolt, and the like) as well as size. As shown above, embodiments of the present invention includes various stress relief patterns and depths as illustrated above in FIGS. 1-5, with some patterns more suitable over others.

The head of the fastener 115 is proportional to the surface area directly secured. For example, a screw with a large head, occupies and secures a greater surface area of the underlying substrate than that of the head of a nail. The underlying substrate becomes increasingly less flexible (and inversely more secure) near the center of the screw. Accordingly, a stress relief pattern for the screw may need to begin further from the center of the fastener hole for the screw than that of the center of a fastener hole for the nail.

Further embodiments may also consider the type of fastener material (e.g., iron, steel, lead, aluminum, plastic, and the like). In such a embodiments, a plastic screw anchor may have larger threads than a steel screw and thus, exhibit slightly less compression force against the substrate 128.

The method 600 continues to step 625 to analyze the thickness of the substrate 128. The thickness of the substrate as well as the material composition of the substrate are analyzed to determine the typical stress and strain factors for a single continuous portion of the substrate 128. Factors contributing to step 625 includes yield strength, yield point, elastic limit, elastic modulus, bending modulus, yield stress, break strength, and the like. Such factors contribute to the flexibility or stiffness of the substrate 128.

The method 600 continues to step 630 to determine whether the fastener hole is near another fastener hole. The proximity between holes is considered as a reduction in substrate material between holes of close proximity may detrimentally affect the flexibility and ductility of the substrate 128. If the method determines another hole is near, the method 600 ends at step 632.

However, if the method 600 determines no holes are near, the method continues to step 635 to select the stress relief pattern as determined based on factors from Steps 620-630. The method 600 continues to step 640 select an excavation depth of the stress relief pattern into the substrate 128. In some embodiments, the depth may comprise a partial slot, and in other embodiments the pattern may comprise a through channel, or a combination of slots and channels. The method 600 continues to step 645 to excavate the substrate material (e.g., via dremel, drill, and the like).

The method 600 then determines at step 650 as to whether more fastener holes are necessary to secure the substrate. If the method 600 determines more holes are necessary, the method returns to step 610. However, if no additional fastener holes are necessary, the method ends at step 632.

While foregoing is directed to various embodiments of the present invention, other and further embodiments of the invention may be devised without departing from the basic scope thereof, and the scope thereof is determined by the claims that follow.

1. A continuous substrate comprising:
a first portion with a plurality of electronic components;
at least one strain relief area located proximate a fastening location, and
wherein the at least one strain relief area is located between the first portion and the fastening location.

2. The substrate of claim 1, further comprising a top surface and a bottom surface, and wherein the fastening location comprises a fastener through hole.

3. The substrate of claim 2, wherein the at least one strain relief area has a reduced thickness with respect to the thickness of the first portion that increases ductility to allow the first portion to be substantially stable.

4. The substrate of claim 3, wherein the at least one strain relief area is continuous and substantially surrounds the fastener through hole.

5. The substrate of claim 3, wherein the at least one strain relief area comprises at least two symmetrical unconnected continuous areas concentric to the fastener through hole.

6. The substrate of claim 3, wherein the at least one strain relief area includes a first relief area and a second relief area concentric to the fastener through hole.

7. The substrate of claim 2, wherein the at least one strain relief area is a channel between the top surface and bottom surface.

8. The substrate of claim 7, wherein the at least one strain relief area is continuous and substantially surrounds the fastener through hole.

9. The substrate of claim 7, wherein the at least one strain relief area comprises at least two uniform unconnected continuous areas concentric to the fastener through hole.

10. The substrate of claim 7, wherein the at least one strain relief area includes a first relief region and a second relief region concentric to the fastener through hole.

11. A substrate comprising:
a fastener hole;
a first pair of arcuate strain relief areas concentric to the fastener hole, each located to opposite sides of the fastener hole; and
a second pair of arcuate strain relief areas concentric to the fastener hole, and partially encompassing the first pair of arcuate strain relief areas.

12. The substrate of claim 11, wherein the first pair of arcuate strain relief areas comprise regions a reduced thickness with respect to the substrate.

13. The substrate of claim 12, wherein the reduced thickness is tapered from the thickness of the substrate.

14. The substrate of claim 11, wherein the first pair of arcuate strain relief areas comprise channels connecting a top surface and bottom surface of the substrate.

15. The substrate of claim 11, wherein the first pair of arcuate strain relief areas are symmetrical.

16. The substrate of claim 11, wherein the first pair of arcuate strain relief areas comprises a smaller area than the second pair of arcuate strain relief areas.

17. The substrate of claim 11, wherein the first and second pairs of arcuate strain relief areas are concentric to the fastener through hole.

18. The substrate of claim 11, wherein the substrate is a single continuous piece of material.

19. The substrate of claim 11, wherein the first pair of arcuate strain relief areas further comprises channels connecting a top surface and bottom surface of the substrate, and the second pair of arcuate strain relief areas further comprises areas of reduced thickness with respect to the substrate.

20. The substrate of claim 11, wherein spacing between the first pair of arcuate strain relief areas and the fastener through hole is the same as the spacing between the second pair of arcuate strain relief areas and the first pair of arcuate strain relief areas.
